(19) United States
(12) Patent Application Publication
(10) Pub. No.: US 2026/0230035 A1
(43) Pub. Date: Aug. 6, 2026

(54) Electricity-Generating Photovoltaic System

(71) Applicant: Naeem Umar, Desert Hot Springs, CA (US)

(72) Inventor: Naeem Umar, Desert Hot Springs, CA (US)

(21) Appl. No.: 19/264,173

(22) Filed: Jul. 9, 2025

Related U.S. Application Data
(60) Provisional application No. 63/754,351, filed on Feb. 5, 2025.

(51) Int. Cl. H02S 30/20; H02S 40/22

(52) U.S. Cl. CPC H02S 30/20; H02S 40/22

(57) ABSTRACT

An electricity-generating photovoltaic system is a system that efficiently converts solar energy into electricity while taking less operational space when compared to traditional solar panels. The system includes at least one solar tube, at least one retractable panel mechanism, and a support structure. The at least one solar tube corresponds to a vertical structure that captures sunlight to be converted into electricity. The at least one solar tube also includes means to efficiently convert the captured sunlight into electricity. The at least one retractable panel mechanism enables the control of the travel of the captured sunlight down the at least one solar tube. The support structure provides structural support for the at least one solar tube to maintain a desired orientation. The support structure also provides structural support to the at least one retractable panel mechanism to enable the automatic operation of the system.

### FIELD OF THE INVENTION

The present invention generally relates to renewable energy systems. More specifically, the present invention provides a novel photovoltaic system that implements thin film photovoltaic formulas to absorb up to three times more solar energy while taking less space.

### BACKGROUND OF THE INVENTION

Renewable energy has increased in popularity over the years due to the lower environmental impact compared to other energy sources, such as oil and gas. One of the most popular renewable energy sources is solar energy as solar energy is the most abundant renewable energy source. Generally, a solar panel is utilized to convert solar energy into an electrical current that can be used to power different electrical/electronic devices. Different solar panel technologies have been developed to increase the efficiency of electrical power generation. However, one of the major disadvantages of solar panel technology is the amount of space necessary to generate the desired electrical power. Most available solar panels utilize a large operating space since most solar panels require a large surface area to generate the desired electrical power. This largely limits the implementation of solar panels in many locations that do not have large spaces available for solar panels. In addition, to match the large-scale power output that other energy sources can achieve, several large solar panels need to be installed in a large location, often referred to as a solar farm. Therefore, a photovoltaic system that can efficiently convert solar energy into electrical energy without taking too much space is beneficial and necessary.

### SUMMARY OF THE INVENTION

The present invention discloses an electricity-generating photovoltaic system that efficiently generates electricity without being limited by the available horizontal space on which the system is installed. In the preferred embodiment, the system of the present invention discloses a vertical structure that includes one or more solar tubes designed to capture and convert solar energy into electricity. Each of the solar tubes includes a filament core that captures and guides the captured sunlight along the length of the solar tube. In addition, each of the solar tubes has an outer photovoltaic jacket that surrounds the filament core. The photovoltaic jacket includes a photovoltaic formula that absorbs the captured sunlight and converts the solar energy into electricity.

In some embodiments, several solar tubes can be vertically stacked on top of each other with a retractable panel installed in between each to control the travel of the captured sunlight down the stacked solar tubes. The retractable panel can be selectively deployed to prevent the captured sunlight from travelling from one solar tube to the next. Alternatively, the retractable panel can be selectively stored away to enable the captured sunlight to travel from one solar tube to the next. Furthermore, several design factors of the system including, but not limited to, the thickness of the filament core, the filament lateral opacity, the photovoltaic formula opacity, etc., can be adjusted to accommodate specific operational specifications or light conditions. Additional features and benefits of the present invention are further discussed in the sections below.

### BRIEF DESCRIPTION OF THE DRAWINGS

FIG. 1 is a top-front-left perspective view of the present invention, wherein the soft panel of the retractable panel mechanism is shown in a stored-panel configuration.

FIG. 2 is a bottom-front-left perspective view of the present invention thereof.

FIG. 3 is a left view of the present invention thereof.

FIG. 4 is a vertical cross-sectional view of the present invention taken along line4-4shown in FIG. 3.

FIG. 5 is a magnified view of the first jacket base of the photovoltaic jacket of the present invention shown in FIG. 4.

FIG. 6 is a top-front-left perspective view of the present invention, wherein the soft panel of the retractable panel mechanism is shown in a deployed-panel configuration.

FIG. 7 is a bottom-front-left perspective view of the present invention thereof.

FIG. 8 is a top-front-left perspective view showing the captured sunlight travelling down the optic filaments of the present invention.

FIG. 9 is a magnified view of the photovoltaic lateral wall of the photovoltaic jacket of the present invention, wherein the captured sunlight is shown being absorbed by the photovoltaic layer.

FIG. 10 is a left view of the present invention, wherein several solar tubes and retractable panel mechanisms are shown stacked in a vertical arrangement, and wherein the soft panels of the retractable panel mechanisms are shown in the deployed-panel configuration.

FIG. 11 is a vertical cross-sectional view of the present invention taken along line 11-11 shown in FIG. 10.

FIG. 12 is a left view of the present invention, wherein several solar tubes and retractable panel mechanisms are shown stacked in a vertical arrangement, and wherein the soft panels of the retractable panel mechanisms are shown in the stored-panel configuration.

FIG. 13 is a vertical cross-sectional view of the present invention taken along line 13-13 shown in FIG. 12.

FIG. 14 is a top-front-left perspective view of the present invention, wherein several stacks of solar tubes are shown arranged to form a large panel assembly.

FIG. 15 is a top-front-left exploded perspective view of the present invention, wherein several stacks of solar tubes are shown arranged in a large panel assembly.

FIG. 16 is a top-front-left perspective view of the present invention, wherein several stacks of solar tubes are shown arranged in a large panel assembly.

FIG. 17 is a top-front-left perspective view of the present invention, wherein several stacks of solar tubes are shown arranged in a large panel assembly forming a multi-junction solar panel assembly.

FIG. 18 is a top-front-left perspective view of the present invention, wherein the thickness and lateral opacity of the optic filaments and photovoltaic jackets are reduced to absorb solar energy while allowing sunlight to shine through.

FIG. 19 is a top-front-left perspective view of the present invention, wherein the thickness and lateral opacity of the optic filaments and photovoltaic jackets are increased to absorb solar energy in locations with higher light intensity.

FIG. 20 is a box diagram showing the electrical connections and the electronic connections of the present invention, wherein the electrical connections are shown in solid lines, and wherein the electronic connections are shown in dashed lines.

FIG. 21 is a left view of the present invention, wherein several solar tubes and retractable panel mechanisms are shown stacked in a vertical arrangement, and wherein the soft panels of the retractable panel mechanisms are shown in the deployed-panel configuration.

### DETAIL DESCRIPTIONS OF THE INVENTION

All illustrations of the drawings are for the purpose of describing selected versions of the present invention and are not intended to limit the scope of the present invention.

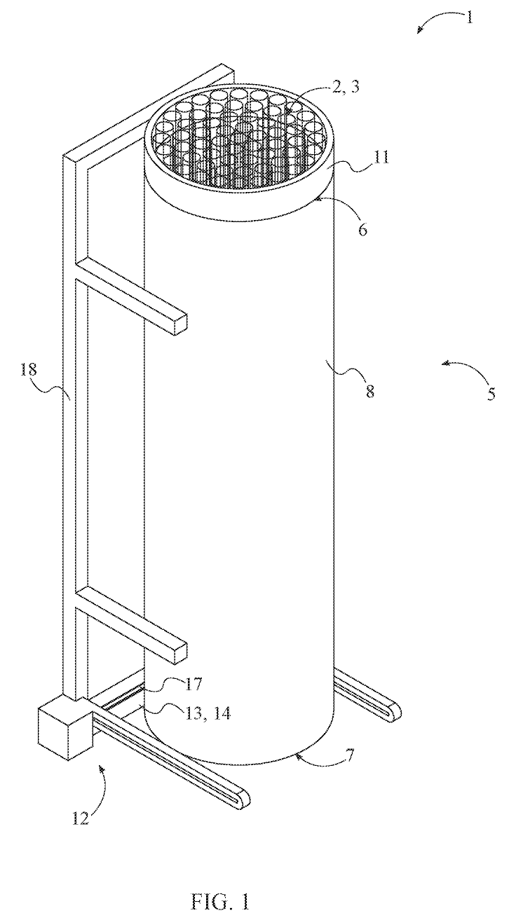

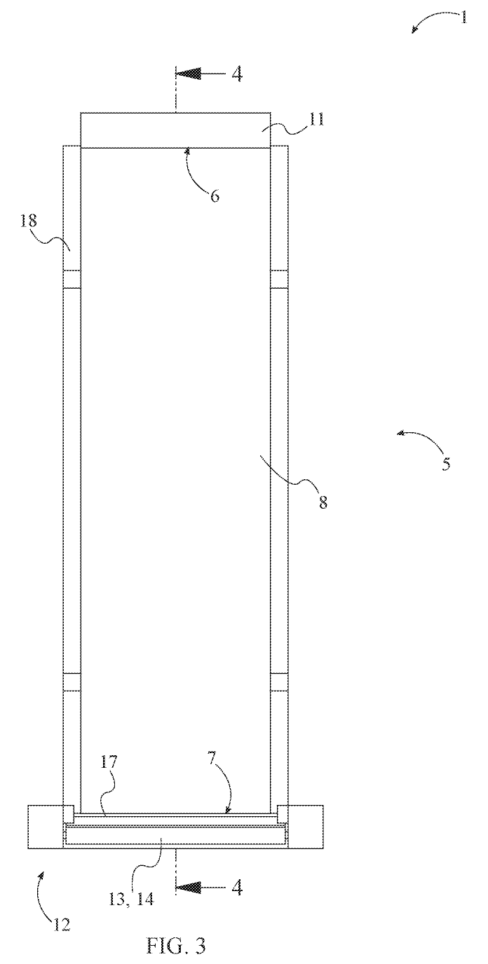

The present invention discloses an electricity-generating photovoltaic system that efficiently converts solar energy into electricity while taking less operational space when compared to traditional solar panels. In the preferred embodiment, the present invention comprises at least one solar tube 1, at least one retractable panel mechanism 12, and a support structure 18, as can be seen in FIG. 1 through 7. The at least one solar tube 1 corresponds to a vertical structure that captures sunlight to be converted into electricity. The at least one retractable panel mechanism 12 enables the control of travel of the captured sunlight down the at least one solar tube 1. The support structure 18 provides structural support for the at least one solar tube 1 and the at least one retractable panel mechanism 12 to enable the automatic operation of the system.

The general configuration of the aforementioned components enables the efficient generation of electricity using solar energy without requiring a large horizontal operational space. As can be seen in FIG. 1 through 7, the at least one solar tube 1 is preferably designed with a cylindrical shape that is generally oriented vertically towards the sun. In the preferred embodiment, the at least one solar tube 1 comprises at least one optic filament 2 and a photovoltaic jacket 5. The at least one optic filament 2 corresponds to the core of the at least one solar tube 1, while the photovoltaic jacket 5 corresponds to the structure that encloses the lateral sides of the at least one optic filament 2. Further, due to the cylindrical design of the at least one solar tube 1, the at least one optic filament 2 and the at least one retractable panel mechanism 12 also have an overall cylindrical design. So, the at least one optic filament 2 comprises a first filament end 3 and a second filament end 4 corresponding to the terminal ends of the at least one optic filament 2. Similarly, the photovoltaic jacket 5 comprises a first jacket base 6, a second jacket base 7, and a photovoltaic lateral wall 8. The first jacket base 6 and the second jacket base 7 correspond to the terminal bases of the photovoltaic jacket 5, while the photovoltaic lateral wall 8 corresponds to the lateral structure of the photovoltaic jacket 5.

In the preferred embodiment, the present invention can be implemented as follows: the photovoltaic lateral wall 8 is laterally mounted onto the support structure 18 so that the orientation of the at least one solar tube 1 is maintained by the support structure 18, as can be seen in FIG. 1 through 7. The support structure 18 can include different designs depending on the overall specifications of the system. For example, the support structure 18 can be a vertical truss structure large enough to maintain the orientation of the at least one solar tube 1. Several mechanisms can be implemented to facilitate the automated or manual adjustment of the orientation of the at least one solar tube 1.

Further, the at least one optic filament 2 is mounted within the photovoltaic lateral wall 8 to secure the photovoltaic jacket 5 to the at least one optic filament 2 and form a single structure, as can be seen in FIG. 1 through 7. The at least one optic filament 2 spans the length of the photovoltaic jacket 5. So, the first filament end 3 is positioned adjacent to the first jacket base 6 and the second filament end 4 is positioned adjacent to the second jacket base 7. Further, the at least one retractable panel mechanism 12 is positioned adjacent to the second jacket base 7. In addition, the at least one retractable panel mechanism 12 is operatively mounted onto the support structure 18 to secure the at least one retractable panel mechanism 12 to the support structure 18. The at least one retractable panel mechanism 12 is used to selectively cover the second jacket base 7 to limit the outflow of the captured sunlight through the second filament end 4. Different mechanisms can be employed that allow the selective engagement of the at least one retractable panel mechanism 12, either manually or automatically. In other embodiments, the system of the present invention can be altered to accommodate other features that enhance the functionality of the system.

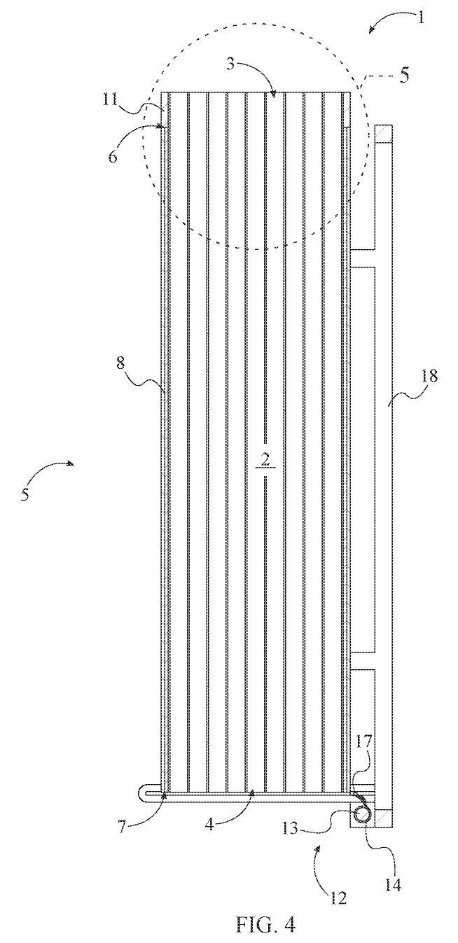

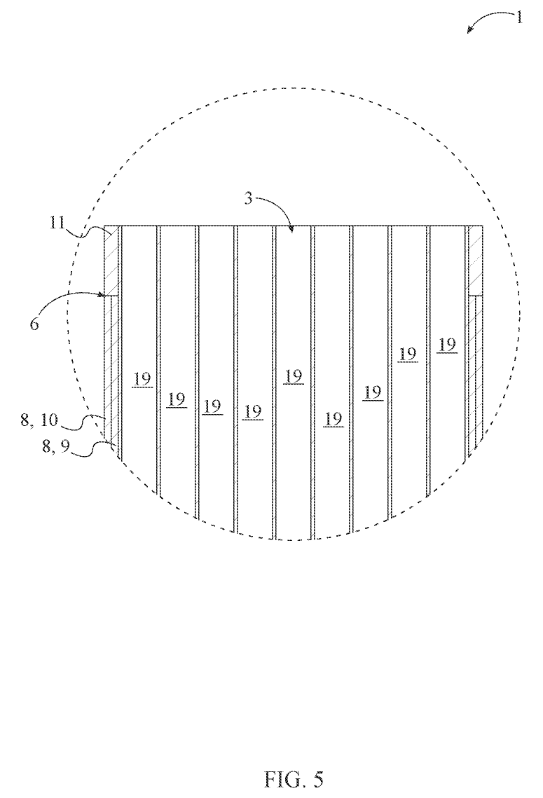

The at least one optic filament 2 can be provided as a single structure that facilitates the capturing of sunlight. In addition, the at least one optic filament 2 is designed to guide the travel of sunlight along the length of the at least one optic filament 2. However, to increase the efficiency of sunlight absorption by the photovoltaic jacket 5, the at least one optic filament 2 can be provided as a plurality of optic filaments 19, as can be seen in FIG. 4 and 5. The plurality of optic filaments 19 is provided as a bundle of filaments laterally enclosed by the photovoltaic jacket 5. So, the plurality of optic filaments 19 is positioned parallel to each other so that the plurality of optic filaments 19 can be evenly distributed within the photovoltaic lateral wall 8. The plurality of optic filaments 19 can be adjusted to control the travel of sunlight through the optic filament by changing different factors including, but not limited to, the thickness of the optic filaments, the lateral opacity of the optic filaments, etc. In other embodiments, the plurality of optic filaments 19 can be altered to increase the overall efficiency of the system.

As previously discussed, the photovoltaic jacket 5 is designed to absorb the captured sunlight to convert the solar energy into electricity. As can be seen in FIG. 1 through 7, the photovoltaic lateral wall 8 may comprise a photovoltaic layer 9 and a backing layer 10. The photovoltaic layer 9 corresponds to the portion of the photovoltaic lateral wall 8 composed of the photovoltaic formula that converts the solar energy into the electricity. The backing layer 10 supports the photovoltaic layer 9 and protects the photovoltaic layer 9 from environmental damage. In general, the photovoltaic layer 9 is oriented towards the at least one optic filament 2, while the backing layer 10 is oriented away from the at least one optic filament 2. Different materials can be implemented for both the photovoltaic layer 9 and the backing layer 10 depending on the technologies available as well as the system specifications. In other embodiments, the photovoltaic jacket 5 can be modified to accommodate other electricity-generating features and mechanisms.

In the preferred embodiment, the at least one retractable panel mechanism 12 generally is designed to deploy a thin piece of reflective material that reflects the captured sunlight reaching the second jacket base 7 back up the at least one optic filament 2 to increase the absorption of the captured sunlight. As a result, the electricity generation by the system is increased without having to increase the overall length of the at least one solar tube 1. As can be seen in FIG. 1 through 7, the at least one retractable panel mechanism 12 comprising a motorized roller 13, a soft panel 14, and a panel guide 17. The motorized roller 13 corresponds to the portion of the mechanism that facilitate the deployment and storage of the soft panel 14. The soft panel 14 corresponds to an elongated piece of reflective material large enough to cover the second jacket base 7. So, the soft panel 14 comprises a fixed panel edge 15 and a free panel edge 16 corresponding to opposite edges of the soft panel 14. Further, the panel guide 17 facilitates the deployment and storage of the soft panel 14 along the support structure 18 to prevent damage to the soft panel 14.

In general, this embodiment of the at least one retractable panel mechanism 12 can be implemented as follows: the panel guide 17 is positioned parallel to the second jacket base 7, as can be seen in FIG. 1 through 7. This way, when the panel guide 17 is moving, the panel guide 17 does not hit the second jacket base 7. Further, the panel guide 17 is slidably mounted onto the support structure 18 to secure the panel guide 17 to the support structure 18. For example, one or more channels parallel to the second jacket base 7 can be implemented in the support structure 18 that guides the movement of the panel guide 17.

Further, the motorized roller 13 is oriented perpendicular to the photovoltaic jacket 5 to prevent the soft panel 14 from being damaged when being deployed/stored, as can be seen in FIG. 1 through 7. The motorized roller 13 can include different types of electric motors powerful enough to rotate the shaft of the roller. In addition, the motorized roller 13 is rollably mounted onto the support structure 18 so that soft panel 14 can be coiled around the motorized roller 13 for safe storage. Further, the fixed panel edge 15 is laterally connected along the motorized roller 13 to secure the soft panel 14 to the motorized roller 13. On the other hand, the free panel edge 16 is laterally connected along the panel guide 17 to secure the panel guide 17 to the soft panel 14. This way, the rotation of the motorized roller 13 drives the deployment or storage of the soft panel 14. For example, when the motorized roller 13 is rotated clockwise, the soft panel 14 is coiled around the motorized roller 13. When the motorized roller 13 is rotated counterclockwise, the soft panel 14 is uncoiled from the motorized roller 13. As the soft panel 14 is uncoiled, the panel guide 17 slides along the support structure 18 to position the soft panel 14 coextensive with the second jacket base 7.

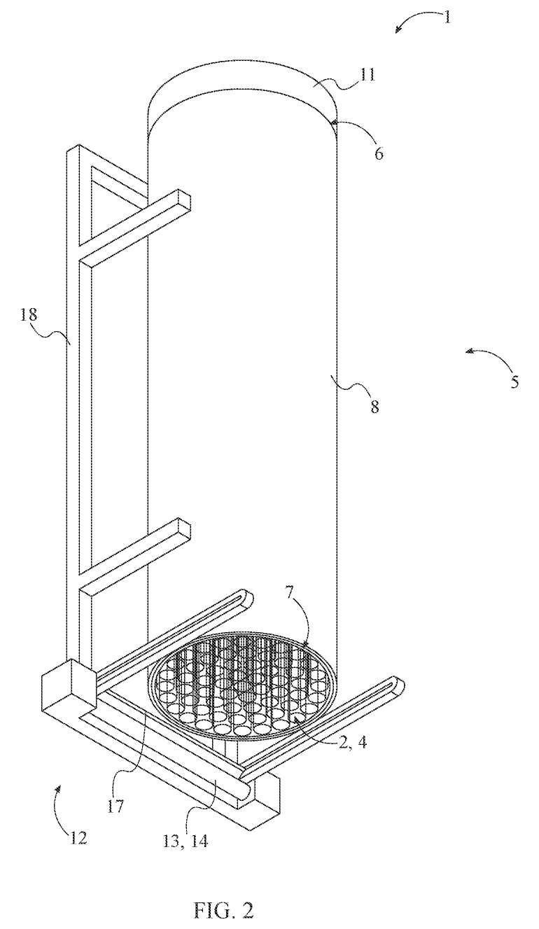

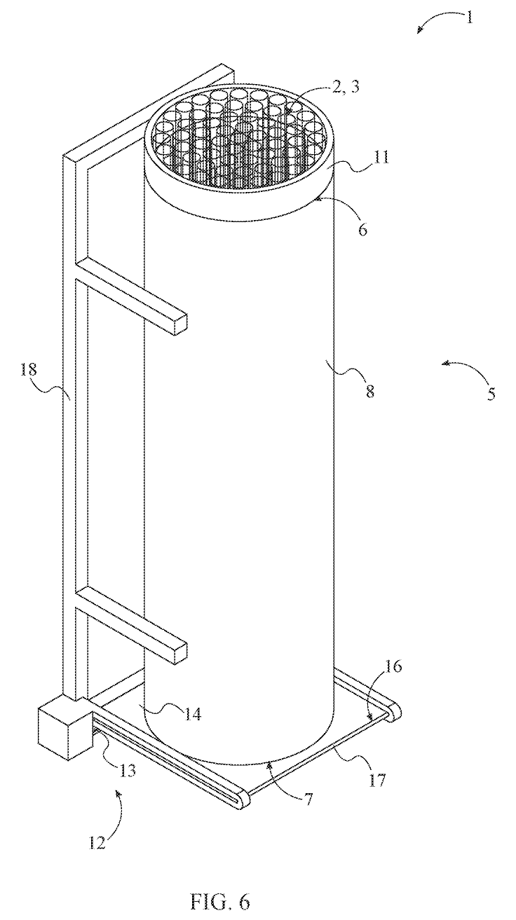

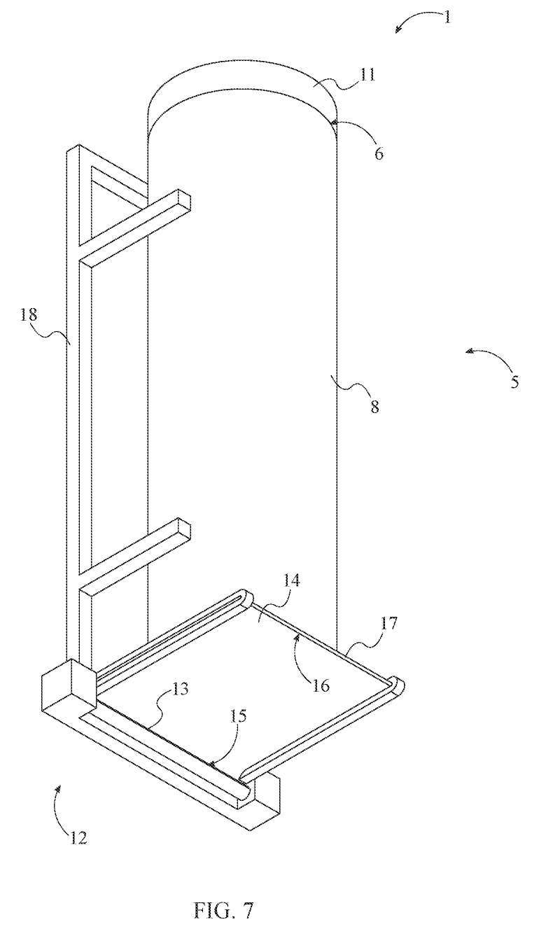

This embodiment of the at least one retractable panel mechanism 12 allows the implementation of different configurations. In a deployed-panel configuration, the soft panel 14 and the panel guide 17 are arranged to cover the second jacket base 7, as can be seen in FIG. 6 and 7. In the deployed-panel configuration, the soft panel 14 is uncoiled from the motorized roller 13 and the panel guide 17 is positioned offset to the motorized roller 13. The panel guide 17 moves past the second jacket base 7 so that second jacket base 7 can be enclosed by the soft panel 14. On the other hand, in a stored-panel configuration, the soft panel 14 and the panel guide 17 are arranged to uncover the second jacket base 7 so that the captured sunlight can exit through the second filament end 4, as can be seen in FIG. 1 and 2. In the stored-panel configuration, the soft panel 14 is coiled around the motorized roller 13 until the panel guide 17 is positioned adjacent to the motorized roller 13. In other embodiments, different mechanisms can be implemented that allow the selective deployment and storage of the soft panel 14.

Depending on the material used for the at least one optic filament 2, some of the sunlight may be reflected off the first filament end 3 without traveling down the at least one optic filament 2. As can be seen in FIG. 1 through 7, to promote the capturing of sunlight by the at least one optic filament 2, the at least one solar tube 1 may further comprise a reflective band 11 that minimizes the loss of sunlight at the first filament end 3. To do so, the reflective band 11 is axially aligned with the photovoltaic lateral wall 8 to match the cylindrical design of the at least one solar tube 1. In addition, the reflective band 11 is terminally connected to the first jacket base 6 to secure the reflective band 11 to the photovoltaic jacket 5. This way, when the sunlight hits the first filament end 3, the reflective band 11 reflects most of the light bouncing off the first filament end 3 into the at least one optic filament 2.

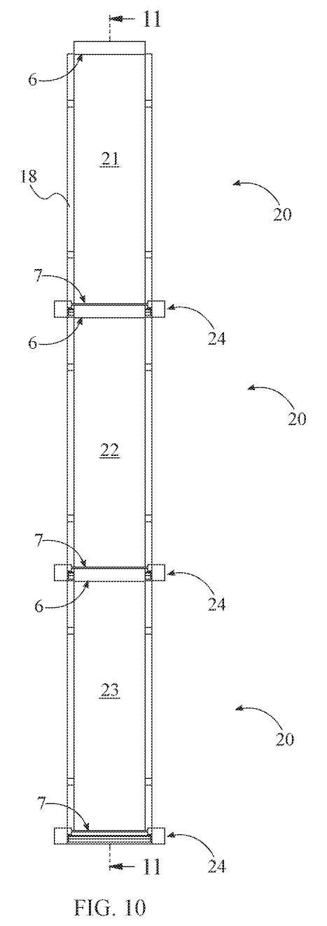

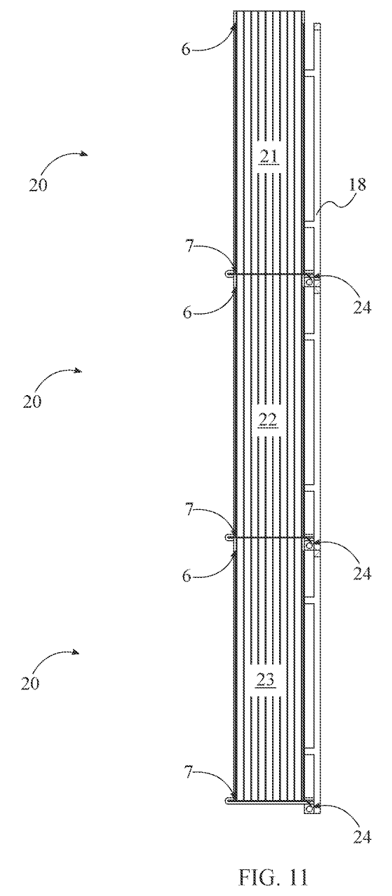

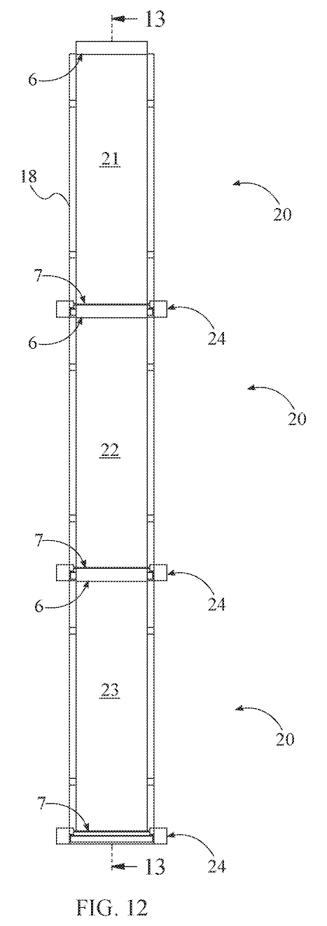

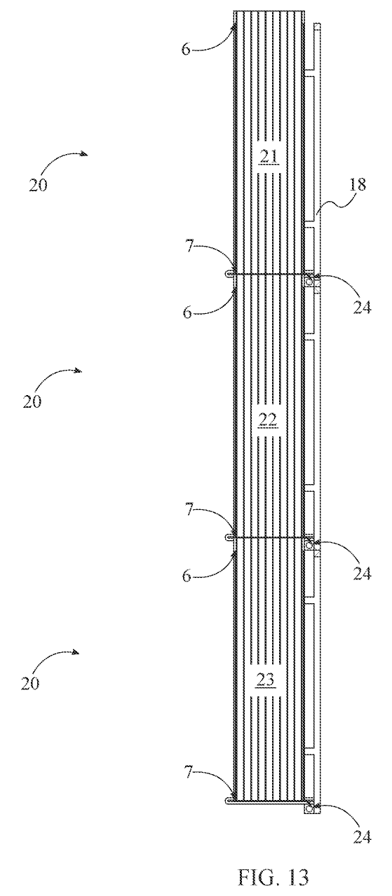

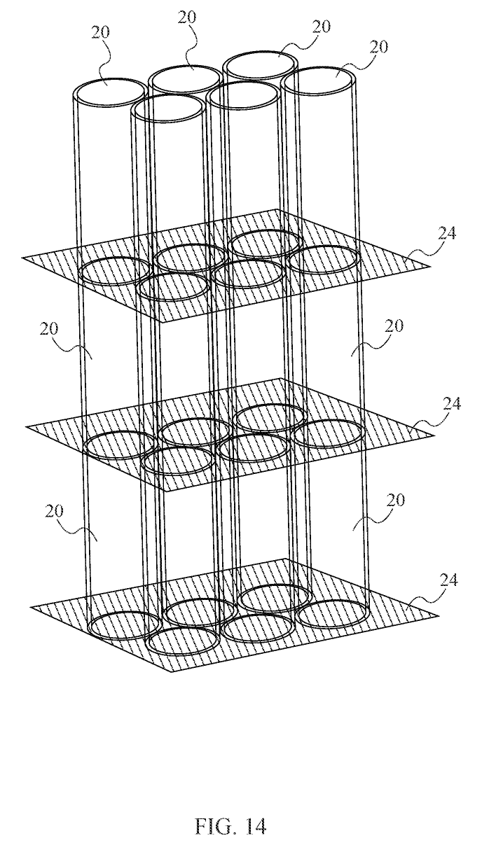

As previously discussed, the system of the present invention can include several solar tubes vertically arranged to increase the sunlight absorption by the photovoltaic jacket 5. As can be seen in FIG. 10 through 14, the at least one solar tube 1 can be provided with a plurality of solar tubes 20, each being the same size. In addition, the at least one retractable panel mechanism 12 can be provided as a plurality of retractable panel mechanisms 24 to selectively cover the second jacket base 7s of the plurality of solar tubes 20. Further, the vertically stacking of the plurality of solar tubes 20 results in a general arrangement of two solar tubes placed at each end of the vertical stack and one or more intermediate stacks placed between the terminal solar tubes. So, the plurality of solar tubes 20 may comprise an upper terminal tube 21, at least one intermediate tube 22, and a lower terminal tube 23. Furthermore, the entire assembly can be topped by a non-reflective covering that allows sunlight to shine through. The non-reflective covering can be any type of transparent material such as glass that provides protection to the system without obstructing the sunlight. In other embodiments, different protective features can be implemented.

The plurality of solar tubes 20 can be arranged as follows: the plurality of solar tubes 20 is distributed along the support structure 18 to form the vertical stack of solar tubes, as can be seen in FIG. 10 through 14. The plurality of solar tubes 20 is also axially aligned with each other to form a vertical cylindrical assembly. Further, the upper terminal tube 21 is positioned opposite the lower terminal tube 23 across the at least one intermediate tube 22 due to the vertical stacking of the plurality of solar tubes 20. In addition, due to the vertical stacking of the plurality of solar tubes 20, the first jacket base 6 of the at least one intermediate tube 22 is positioned adjacent to the second jacket base 7 of the upper terminal tube 21. A retractable panel mechanism from the plurality of retractable panel mechanisms 24 is also positioned in between the first jacket base 6 of the at least one intermediate tube 22 and the second jacket base 7 of the upper terminal tube 21 to selectively cover the second jacket base 7 of the upper terminal tube 21.

In addition, the first jacket base 6 of the lower terminal tube 23 is positioned adjacent to the second jacket base 7 of the at least one intermediate tube 22 according to the vertical stack of the plurality of solar tubes 20, as can be seen in FIG. 10 through 14. Similarly, another retractable panel mechanism from the plurality of retractable panel mechanisms 24 is positioned in between the first jacket base 6 of the lower terminal tube 23 and the second jacket base 7 of the at least one intermediate tube 22. This way, the second jacket base 7 of the at least one intermediate tube 22 can be covered by another retractable panel mechanism. As a result, the travel of the captured sunlight along the vertical stack of the plurality of solar tubes 20 can be controlled using the plurality of retractable panel mechanisms 24.

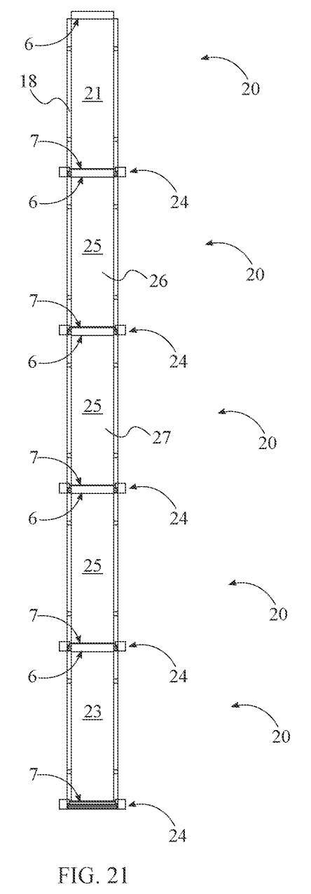

Depending on the system specifications, several solar tubes can be stacked to increase the absorption rate of the capture sunlight which results in greater electricity generation. In such embodiments, the at least one intermediate tube 22 can be provided as a plurality of intermediate tubes 25 since there are always going to be two terminal solar tubes on each stack, as can be seen in FIG. 21. Due to several intermediate tubes, the first jacket base 6 of an arbitrary intermediate tube 26 is positioned adjacent to the second jacket base 7 of an adjacent intermediate tube 27. The arbitrary intermediate tube 26 and the adjacent intermediate tube 27 are any pair of adjacent intermediate tube 27s from the plurality of intermediate tubes 25, which includes the intermediate tubes adjacent to the terminal solar tubes. Further, a retractable panel mechanism from the plurality of retractable panel mechanisms 24 is positioned in between the first jacket base 6 of the arbitrary intermediate tube 26 and the second jacket base 7 of the adjacent intermediate tube 27. In other words, each pair of adjacent intermediate tube 27s has a retractable panel mechanism in between to selectively cover the second jacket base 7 of the arbitrary intermediate tube 26. In other embodiments, different vertical arrangements can be implemented to form a vertical assembly of solar tubes.

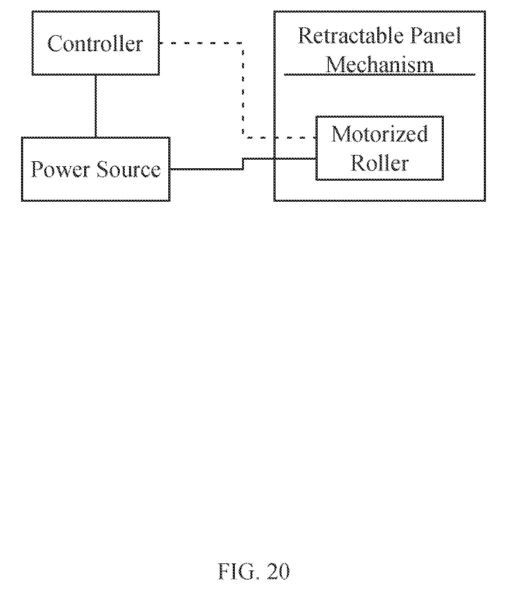

Generally, different technologies can be implemented to control and power the operation of the system of the present invention. For example, the present invention may further comprise a controller 28 that facilitates the direct or remote control of each motorized roller 13 in the system as well as a power source 29 that provides the electrical power necessary for the operation of each motorized roller 13, as can be seen in FIG. 20. The controller 28 can facilitate the direct or remote control of the system by the user. The controller 28 can also facilitate the automatic operation of the system based on predetermined configurations. Further, several monitoring resources including, but not limited to, sensors, gauges, etc., can be implemented to help adjust the operation of the system based on system feedback or environmental factors. Moreover, the power source 29 can be an external power source 29, such as electrical utilities, or an integrated power source 29, such as one or more batteries which can be provided as replaceable or rechargeable batteries. Some of the electricity generated by the system can used to charge the rechargeable batteries.

Generally, the controller 28 and the power source 29 are positioned offset to the at least one solar tube 1 to not obstruct with the operation of the system, as can be seen in FIG. 20. Both the controller 28 and the power source 29 can be implemented within the support structure 18 or external to the support structure 18. If implemented in the support structure 18, the support structure 18 can be modified to accommodate the electronics and the electrical components. In addition, the at least one retractable panel mechanism 12 is electronically connected to the controller 28 so that each motorized roller 13 can be operated via the controller 28. The at least one retractable panel mechanism 12 and the controller 28 are also electrically connected to the power source 29 to distribute the electrical power necessary for the electrical components. In other embodiments, different control and power technologies can be implemented to help control and power the system of the present invention. In addition, the system of the present invention can include a power storage mechanism that collects the electricity generated by the system.

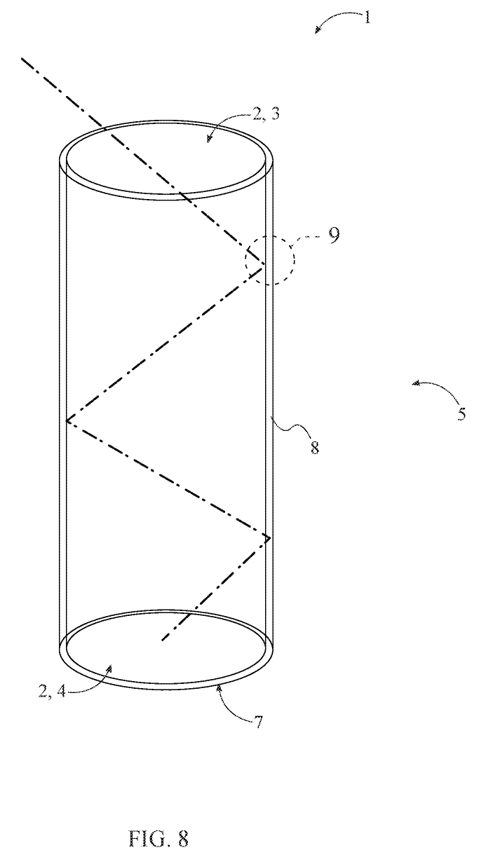

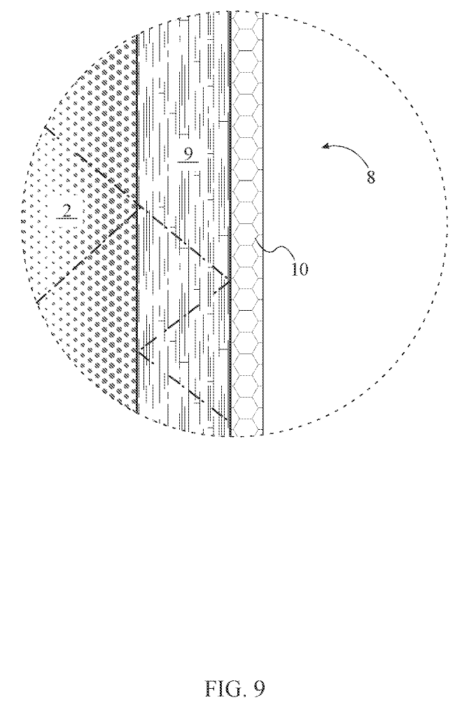

Depending on the system design, the electricity generation is performed based on a method of the present invention. As can be seen in FIG. 8 and 9, the overall process of the present invention begins when sunlight hits the first filament end 3, sunlight is caught inside the at least one optic filament 2. From there, sunlight travels down the at least one optic filament 2 by being reflected down the lateral walls of the at least one optic filament 2. A small amount of light escapes every time the sunlight is reflected within the at least one optic filament 2. The light that escapes through the sides is absorbed by the photovoltaic formula on the photovoltaic layer 9. Any light that is not absorbed is reflected back and forth between the photovoltaic layer 9 and the lateral walls of the at least one optic filament 2 for more chances to be absorbed.

In most fiber optics, any light that does not first pass through the core of the filament (e.g., passing through the clad on the far/adjacent side of the filament relative to the light source) leaves the filament entirely, never getting a chance to be reflected through the filament. The reflective band 11 minimizes this loss and can be made from reflective, corrosion resistant, conductive material such as silver. With the reflective band 11, most sunlight that enters through the first filament end 3 without passing through the core is reflected into the core of the at least one optic filament 2. The conductive properties of the reflective band 11 also assists in carrying charge collected by the photovoltaic layer 9 away.

Any sunlight that reaches the second filament end 4 hits the soft panel 14 which is preferably made from Mylar-like material. All light that hits the soft panel 14 is reflected into the at least one optic filament 2 for reprocessing. This gives the sunlight another chance to saturate the at least one solar tube 1, further exciting the photovoltaic layer 9 to generate more electricity. This ensures that during low light conditions (e.g., cloudy days) most of the sunlight is focused on a smaller area, rather than being allowed to spread out across largest surface areas where the sunlight may become too weak to draw sufficient charge from.

When a plurality of solar tubes 20 is implemented, each soft panel 14 of the upper retractable panel mechanisms can be retracted depending on the light intensity to allow sunlight to reach the lower solar tubes. The sunlight that reaches the second filament end 4 of the upper solar tube continues processing on the solar tube below. If the light reaches the second filament end 4 of the intermediate solar tube, sunlight can be reflected by the soft panel 14 deployed below the second jacket base 7 of the intermediate solar tube to be reprocessed by the intermediate solar tube and the upper solar tube. The sunlight can also be allowed to travel down to the lower solar tubes for further processing. Once the sunlight reaches the lowest solar tube, the remaining light can be reflected into the whole system for final reprocessing by deploying the lowest soft panel 14. Alternatively, the lowest soft panel 14 can be stored away to allow the remaining light to exit the exit.

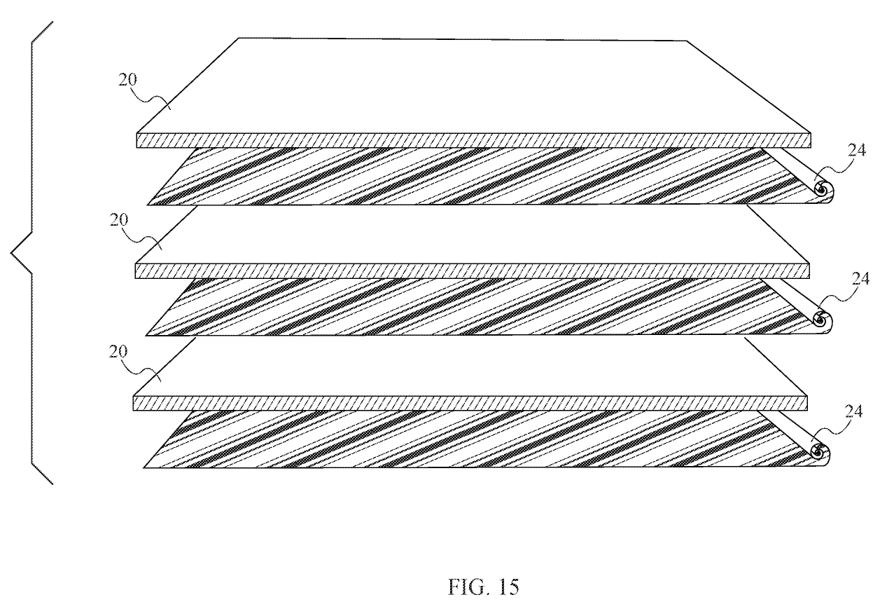

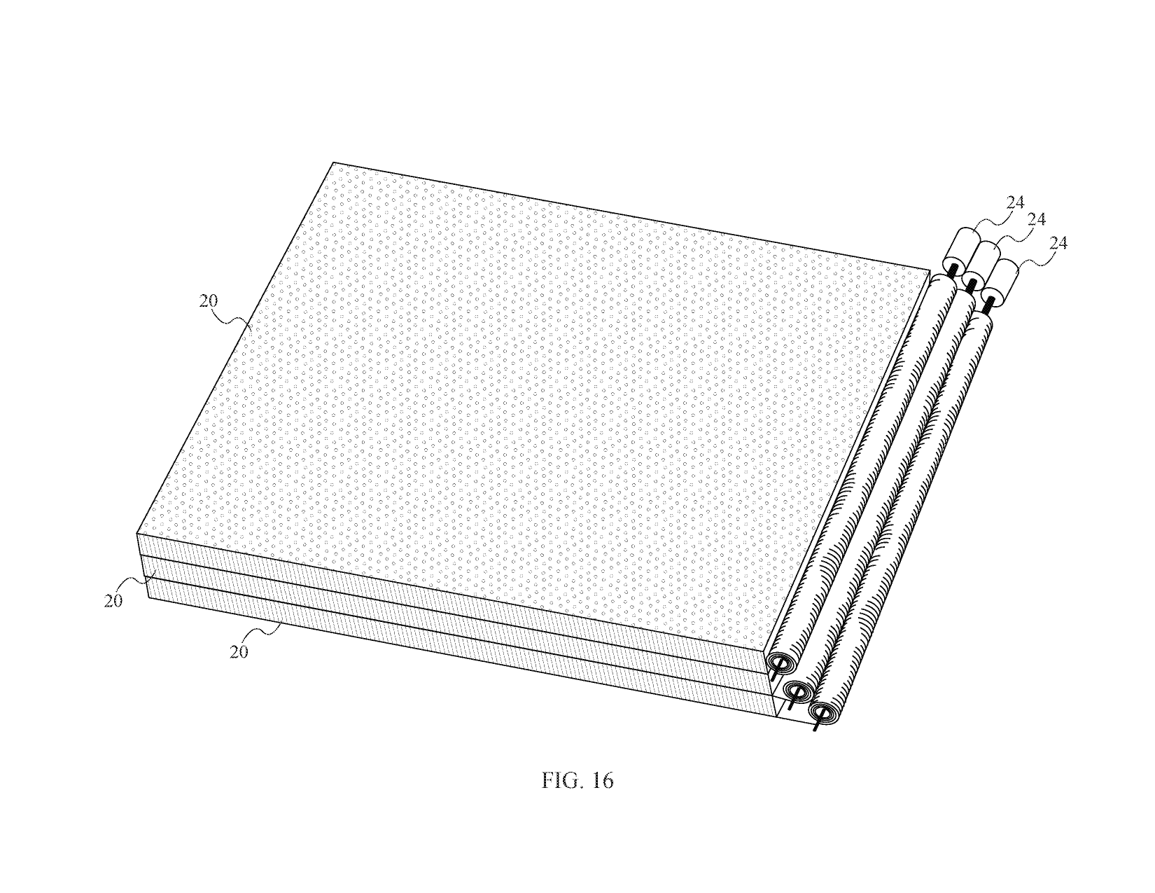

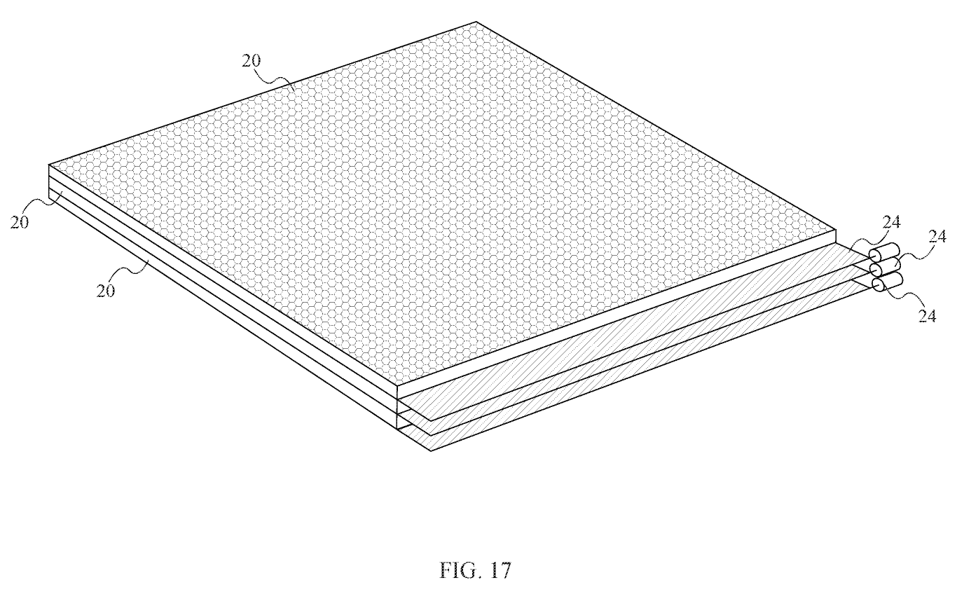

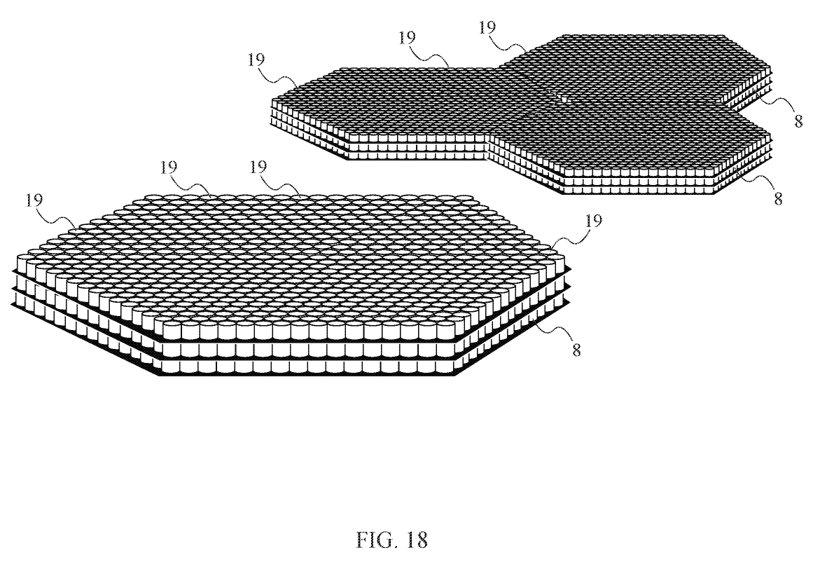

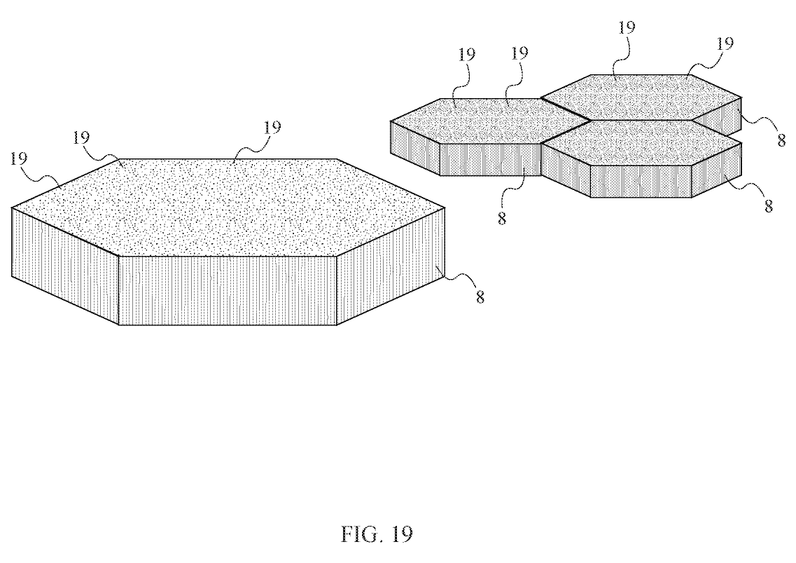

As previously discussed, the thickness of the at least one optic filament 2, the lateral glow opacity, and the photovoltaic layer 9 opacity can be adjusted to suit specific needs and conditions, as can be seen in FIG. 15 through 19. Thicker and more opaque optic filaments can capture more sunlight in locations that receive more sun. Thinner and more transparent optic filaments can absorb solar energy while letting light through. This allows the system to be implemented in a window space to capture solar energy while letting natural light into a building. Overall, the resulting apparatus would be a transparent, vertical multi-junction solar panel assembly that drastically increases the viability of thin film photovoltaic formulas by increasing the chances sunlight can excite the formula and by increasing the surface area of the photovoltaic layer 9 without increasing the operating surface area of the overall assembly.

Although the invention has been explained in relation to its preferred embodiment, it is to be understood that many other possible modifications and variations can be made without departing from the spirit and scope of the invention.

What is claimed is:

1. An electricity-generating photovoltaic system comprising:
at least one solar tube;
at least one retractable panel mechanism;
a support structure;
the at least one solar tube comprising at least one optic filament and a photovoltaic jacket;
the at least one optic filament comprising a first filament end and a second filament end;
the photovoltaic jacket comprising a first jacket base, a second jacket base, and a photovoltaic lateral wall;
the photovoltaic lateral wall being laterally mounted onto the support structure;
the at least one optic filament being mounted within the photovoltaic lateral wall;
the first filament end being positioned adjacent to the first jacket base;
the second filament end being positioned adjacent to the second jacket base;
the at least one retractable panel mechanism being positioned adjacent to the second jacket base; and
the at least one retractable panel mechanism being operatively mounted onto the support structure, wherein the at least one retractable panel mechanism is used to selectively cover the second jacket base.

2. The electricity-generating photovoltaic system as claimed in claim 1 further comprising:
the at least one optic filament being a plurality of optic filaments;
the plurality of optic filaments being positioned parallel to each other; and
the plurality of optic filaments being distributed within the photovoltaic lateral wall.

3. The electricity-generating photovoltaic system as claimed in claim 1 further comprising:
the photovoltaic lateral wall comprising a photovoltaic layer and a backing layer;
the photovoltaic layer being oriented towards the at least one optic filament; and
the backing layer being oriented away from the at least one optic filament.

4. The electricity-generating photovoltaic system as claimed in claim 1 further comprising:
the at least one retractable panel mechanism comprising a motorized roller, a soft panel, and a panel guide;
the soft panel comprising a fixed panel edge and a free panel edge;
the panel guide being positioned parallel to the second jacket base;
the panel guide being slidably mounted onto the support structure;
the motorized roller being oriented perpendicular to the photovoltaic jacket;
the motorized roller being rollably mounted onto the support structure;
the fixed panel edge being positioned opposite the free panel edge along the soft panel;
the fixed panel edge being laterally connected along the motorized roller; and
the free panel edge being laterally connected along the panel guide.

5. The electricity-generating photovoltaic system as claimed in claim 4 further comprising:
wherein the soft panel and the panel guide are arranged into a deployed-panel configuration;
the soft panel being uncoiled from the motorized roller;
the panel guide being positioned offset to the motorized roller; and
the second jacket base being enclosed by the soft panel.

6. The electricity-generating photovoltaic system as claimed in claim 4 further comprising:
wherein the soft panel and the panel guide are arranged into a stored-panel configuration;
the soft panel being coiled around the motorized roller; and
the panel guide being positioned adjacent to the motorized roller.

7. The electricity-generating photovoltaic system as claimed in claim 1 further comprising:
the at least one solar tube further comprising a reflective band;
the reflective band being axially aligned with the photovoltaic lateral wall; and
the reflective band being terminally connected to the first jacket base.

8. The electricity-generating photovoltaic system as claimed in claim 1 further comprising:
the at least one solar tube being a plurality of solar tubes;
the at least one retractable panel mechanism being a plurality of retractable panel mechanisms;
the plurality of solar tubes comprising an upper terminal tube, at least one intermediate tube, and a lower terminal tube;
the plurality of solar tubes being distributed along the support structure;
the plurality of solar tubes being axially aligned with each other;
the upper terminal tube being positioned opposite the lower terminal tube across the at least one intermediate tube;
the first jacket base of the at least one intermediate tube being positioned adjacent to the second jacket base of the upper terminal tube;
a retractable panel mechanism from the plurality of retractable panel mechanisms being positioned in between the first jacket base of the at least one intermediate tube and the second jacket base of the upper terminal tube;
the first jacket base of the lower terminal tube being positioned adjacent to the second jacket base of the at least one intermediate tube; and
another retractable panel mechanism from the plurality of retractable panel mechanisms being positioned in between the first jacket base of the lower terminal tube and the second jacket base of the at least one intermediate tube.

9. The electricity-generating photovoltaic system as claimed in claim 8 further comprising:
the at least one intermediate tube being a plurality of intermediate tubes;
the first jacket base of an arbitrary intermediate tube being positioned adjacent to the second jacket base of an adjacent intermediate tube, wherein the arbitrary intermediate tube and the adjacent intermediate tube are any pair of adjacent intermediate tubes from the plurality of intermediate tubes; and
a retractable panel mechanism from the plurality of retractable panel mechanisms being positioned in between the first jacket base of the arbitrary intermediate tube and the second jacket base of the adjacent intermediate tube.

10. The electricity-generating photovoltaic system as claimed in claim 1 further comprising:
a controller;
a power source;
the controller, the power source, and the power storage mechanism being positioned offset to the at least one solar tube;
the at least one retractable panel mechanism being electronically connected to the controller; and
the at least one retractable panel mechanism and the controller being electrically connected to the power source.

11. An electricity-generating photovoltaic system comprising:
at least one solar tube;
at least one retractable panel mechanism;
a support structure;
the at least one solar tube comprising a plurality of optic filaments and a photovoltaic jacket;
the plurality of optic filaments each comprising a first filament end and a second filament end;
the photovoltaic jacket comprising a first jacket base, a second jacket base, and a photovoltaic lateral wall;
the photovoltaic lateral wall comprising a photovoltaic layer and a backing layer
the photovoltaic lateral wall being laterally mounted onto the support structure;
the photovoltaic layer being oriented towards the plurality of optic filaments;
the backing layer being oriented away from the plurality of optic filaments;
the plurality of optic filaments being positioned parallel to each other;
the plurality of optic filaments being distributed within the photovoltaic lateral wall;
the plurality of optic filaments being mounted within the photovoltaic lateral wall;
each first filament end of the plurality of optic filaments being positioned adjacent to the first jacket base;
each second filament end of the plurality of optic filaments being positioned adjacent to the second jacket base;
the at least one retractable panel mechanism being positioned adjacent to the second jacket base; and
the at least one retractable panel mechanism being operatively mounted onto the support structure, wherein the at least one retractable panel mechanism is used to selectively cover the second jacket base.

12. The electricity-generating photovoltaic system as claimed in claim 11 further comprising:
the at least one retractable panel mechanism comprising a motorized roller, a soft panel, and a panel guide;
the soft panel comprising a fixed panel edge and a free panel edge;
the panel guide being positioned parallel to the second jacket base;
the panel guide being slidably mounted onto the support structure;
the motorized roller being oriented perpendicular to the photovoltaic jacket;
the motorized roller being rollably mounted onto the support structure;
the fixed panel edge being positioned opposite the free panel edge along the soft panel;
the fixed panel edge being laterally connected along the motorized roller; and
the free panel edge being laterally connected along the panel guide.

13. The electricity-generating photovoltaic system as claimed in claim 12 further comprising:
wherein the soft panel and the panel guide are arranged into a deployed-panel configuration;
the soft panel being uncoiled from the motorized roller;
the panel guide being positioned offset to the motorized roller; and
the second jacket base being enclosed by the soft panel.

14. The electricity-generating photovoltaic system as claimed in claim 12 further comprising:
wherein the soft panel and the panel guide are arranged into a stored-panel configuration;
the soft panel being coiled around the motorized roller; and
the panel guide being positioned adjacent to the motorized roller.

15. The electricity-generating photovoltaic system as claimed in claim 11 further comprising:
the at least one solar tube further comprising a reflective band;
the reflective band being axially aligned with the photovoltaic lateral wall; and
the reflective band being terminally connected to the first jacket base.

16. The electricity-generating photovoltaic system as claimed in claim 11 further comprising:
the at least one solar tube being a plurality of solar tubes;
the at least one retractable panel mechanism being a plurality of retractable panel mechanisms;
the plurality of solar tubes comprising an upper terminal tube, at least one intermediate tube, and a lower terminal tube;
the plurality of solar tubes being distributed along the support structure;
the plurality of solar tubes being axially aligned with each other;
the upper terminal tube being positioned opposite the lower terminal tube across the at least one intermediate tube;
the first jacket base of the at least one intermediate tube being positioned adjacent to the second jacket base of the upper terminal tube;
a retractable panel mechanism from the plurality of retractable panel mechanisms being positioned in between the first jacket base of the at least one intermediate tube and the second jacket base of the upper terminal tube;
the first jacket base of the lower terminal tube being positioned adjacent to the second jacket base of the at least one intermediate tube; and
another retractable panel mechanism from the plurality of retractable panel mechanisms being positioned in between the first jacket base of the lower terminal tube and the second jacket base of the at least one intermediate tube.

17. The electricity-generating photovoltaic system as claimed in claim 16 further comprising:
the at least one intermediate tube being a plurality of intermediate tubes;
the first jacket base of an arbitrary intermediate tube being positioned adjacent to the second jacket base of an adjacent intermediate tube, wherein the arbitrary intermediate tube and the adjacent intermediate tube are any pair of adjacent intermediate tubes from the plurality of intermediate tubes; and
a retractable panel mechanism from the plurality of retractable panel mechanisms being positioned in between the first jacket base of the arbitrary intermediate tube and the second jacket base of the adjacent intermediate tube.

18. The electricity-generating photovoltaic system as claimed in claim 11 further comprising:
a controller;
a power source;
the controller and the power source being positioned offset to the at least one solar tube;
the at least one retractable panel mechanism being electronically connected to the controller; and
the at least one retractable panel mechanism and the controller being electrically connected to the power source.
